(19) United States
(12) Patent Application Publication
(10) Pub. No.: US 2008/0222460 A1
(43) Pub. Date: Sep. 11, 2008

(54) Memory test circuit

(75) Inventors: Jaehee Kim, South Burlington, VT (US); Jeon Hwangbo, Williston, VT (US)

Correspondence Address: POSZ LAW GROUP, PLC, 12040 SOUTH LAKES DRIVE, SUITE 101, RESTON, VA, 20191, US

(73) Assignee: Qimonda North America Corp., Cary, NC (US)

(21) Appl. No.: 11/715,429

(22) Filed: Mar. 8, 2007

(51) Int. Cl. G11C 29/04

(52) U.S. Cl. 714/702

(57) ABSTRACT

A memory test circuit is provided, comprising: an output data selector configured to receive the plurality of read data bits and output a fraction of the plurality of read data bits as a plurality of fractional data bits; and a control circuit configured to select a set of bit positions in the plurality of read data bits whose corresponding values will form the plurality of fractional data bits, wherein the selected set of bit positions is selectable from a plurality of possible sets of bit positions, each actual bit position in the plurality of read data bits being contained in at least one of the possible sets of bit positions, and wherein a fractional length of the plurality of fractional data bits is smaller than a full length of the plurality of read data bits.

### BACKGROUND OF THE INVENTION

Integrated circuits are tested after fabrication to ensure that the devices operate properly. However, integrated circuit testers typically have a limited number of resources available for testing devices. The fewer the resources that are needed to test any given device, the more devices can be tested in parallel, allowing more devices to be tested in a shorter period of time using the same testing resources, thus decreasing testing costs.

A typical test of an integrated circuit memory device involves writing data to individual memory cells in the memory device, and then reading the data back from the same memory cells. The data read from the memory cells is then compared to the data written into the memory cells to determine if the process was done without error.

One of the main limited testing resources for memory tests is the testing machines themselves, which are typically very expensive. Each testing machine has a limited number of testing pins available to connect to devices to be tested, thus limiting the number of devices each can test at any given time. And even if they are run almost continuously, each testing machine can only be run so many hours a day, providing a limited number of memory devices that can be tested, based on the time required to perform each test.

Therefore, one way to increase the efficiency of memory tests is to allow each testing machine to test more devices at a given time. This can be achieved by having each testing machine connect to fewer than all of the input/output pins on a given memory device. Another way to increase the efficiency of memory tests is to reduce the amount of time required for any given test.

Some memory devices include an internal data generator that generates test data patterns for testing memory cells in a test mode. The test data patterns are written into memory cells and read back from the memory cells to obtain the comparison results. However, since a testing machine will likely connect to fewer than all of the input/output pins of a memory device, such comparison results are often compressed into a reduced number of outputs that are sent via a correspondingly reduced number of input/output pins.

In such a compression operation, the memory device only reveals whether batches of data are stored and read correctly. It does not provide information for individual data bits. Conventional testing methods therefore involve checking a memory device in a data compression mode to determine general operational success over the entire test pattern, then testing in a normal mode to test some of the true output data. However, since only a limited number of input/output pins are connected to the tester, only a limited number portion of the true data will be examined.

### SUMMARY OF THE INVENTION

A memory test circuit is provided, comprising: an output data selector configured to receive the plurality of read data bits and output a fraction of the plurality of read data bits as a plurality of fractional data bits; and a control circuit configured to select a set of bit positions in the plurality of read data bits whose corresponding values will form the plurality of fractional data bits, wherein the selected set of bit positions is selectable from a plurality of possible sets of bit positions, each actual bit position in the plurality of read data bits being contained in at least one of the possible sets of bit positions, and wherein a fractional length of the plurality of fractional data bits is smaller than a full length of the plurality of read data bits.

### BRIEF DESCRIPTION OF THE DRAWINGS

The accompanying figures where like reference numerals refer to identical or functionally similar elements and which together with the detailed description below are incorporated in and form part of the specification, serve to further illustrate an exemplary embodiment and to explain various principles and advantages in accordance with the present invention.

FIG. 1 is a diagram of a memory test circuit according to disclosed embodiments;

FIG. 2 is a diagram of an output compression element from the memory test circuit of FIG. 1 according to disclosed embodiments;

FIG. 3 is a diagram of a compare circuit from the output compression element of FIG. 2 according to disclosed embodiments;

FIG. 4 is a diagram of an output data selector from the output compression element of FIG. 2 according to disclosed embodiments;

FIG. 5 is a timing diagram of the operation of the memory test circuit of FIG. 1 according to disclosed embodiments; and

FIG. 6 is a flow chart showing a memory testing operation according to disclosed embodiments.

### DETAILED DESCRIPTION

It is understood that the use of relational terms such as first and second, and the like, if any, are used solely to distinguish one from another entity, item, or action without necessarily requiring or implying any actual such relationship or order between such entities, items or actions. It is noted that some embodiments can include a plurality of processes or steps, which can be performed in any order, unless expressly and necessarily limited to a particular order; i.e., processes or steps that are not so limited can be performed in any order.

In addition, reference is made throughout to “high” and “low” bit values or bit values of “1” and “0.” For purposes of explanation a high reference voltage is used to represent a high or “1” bit value and a low reference voltage or ground voltage is used to represent a low or “0” bit value, and many circuit elements are triggered by one or the other bit value. It should be understood that particular voltages could be changed and that the operation of disclosed elements based on particular bit values could be switched around between high and low.

Much of the inventive functionality and many of the inventive principles when implemented can be supported with or in integrated circuits (ICs), such as dynamic random access memory (DRAM) devices or the like. In particular, they can be implemented using CMOS transistors. It is expected that one of ordinary skill, notwithstanding possibly significant effort and many design choices motivated by, for example, available time, current technology, and economic considerations, when guided by the concepts and principles disclosed herein will be readily capable of generating such ICs with minimal experimentation. Therefore, in the interest of brevity and minimization of any risk of obscuring the principles and concepts according to the present invention, further discussion of such ICs will be limited to the essentials with respect to the principles and concepts used by the exemplary embodiments.

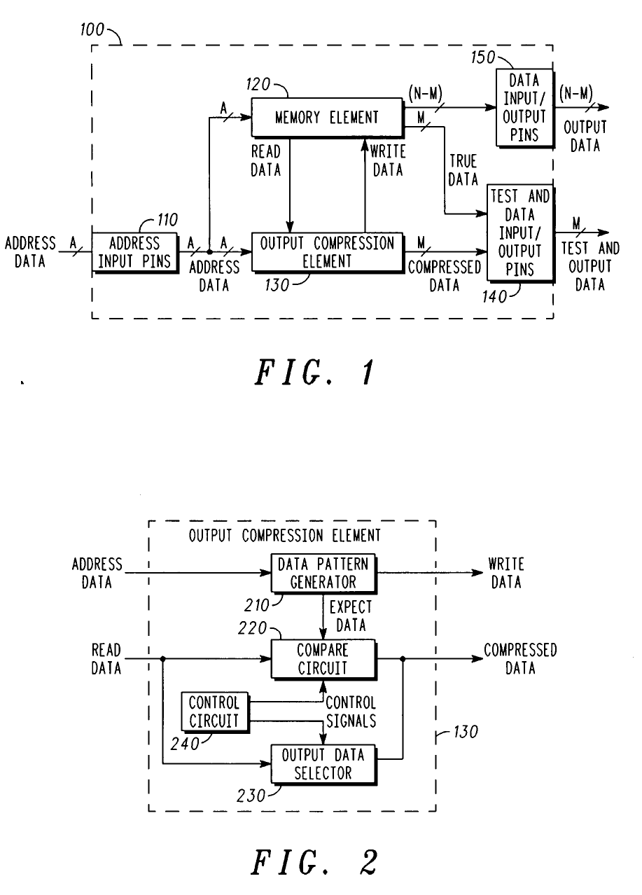

FIG. 1 is a diagram of a memory test circuit according to disclosed embodiments. As shown in FIG. 1, the memory device 100 includes a set of address input pins 110, a memory element 120, an output compression element 130, a set of test and data input/output pins 140, and a set of data input/output pins 150.

The set of address input pins 110 receives a corresponding set of A bits of address data for addressing data within the memory circuit 120, and passes these A bits of address data on to the memory circuit 120 and the output compression element 130. They can be any kind of address pins, as would be understood by one skilled in the art.

The memory circuit 120 is a circuit for storing bits of data. It can be any variety of memory unit whose accuracy may need to be confirmed, e.g., a DRAM, an SRAM, a PRAM, an EPROM, an EEPROM, a flash memory, or the like. The memory element 120 receives the A bits of address data from the address input pins 110, and sends or receives N data bits to or from the data input/output (I/O) pins 150 and the test and data I/O pins 140. In particular, the memory element 120 sends/receives M data bits via the test and data I/O pins 140, and sends/receives (N-M) data bits via the data I/O pins 150.

The memory circuit 120 also receives write data from the output compression element 130 and sends read data to the output compression element 130 for testing purposes. In the disclosed embodiments N bits of write data are sent an N bits of read data are received over the test and data I/O pins 140 and data I/O pins 150 (i.e., over the N total I/O pins), though this can vary in alternate embodiments.

In various embodiments the memory circuit 120 may be subdivided into individual memory cells. In such a case, it may be desirable to test each individual memory cell in the memory circuit 120.

The output compression element 130 receives the A bits of address data from the address input pins and uses them to both send write data to the memory element 120, and then request read data from the memory circuit 120 to check if the write data was successfully written then read. The output compression element 130 then generates a set of M bits of compressed data indicating how successful the writing and reading test operation was performed.

In the disclosed embodiments, A, M, and N are all integers. Furthermore, M is smaller than N, since the number of bits of compressed data are smaller in number than the number of bits of data output from the memory element (i.e. the true data). In addition, in some embodiments M is an integer divisor of N, though other relationships can be used in alternate embodiments.

The set of test and data I/O pins 140 and the set of data I/O pins 150 together pass N true data bits to or from the memory element 120. They can be any kind of data I/O (DQ) pins, as would be understood by one skilled in the art.

In particular, the test and data I/O pins 140 send/receive M data bits, and the data I/O pins 150 send/receive (N-M) data bits. In addition, the test and data I/O pins 140 also pass the M compressed data bits, while the data I/O pins 150 do not pass any compressed data bits.

In addition, the test and data I/O pins 140 are controlled such that during a testing operation (i.e., when the output compression element is providing compression data), the test and data I/O pins 140 will output the compression data, rather than the M bits of true data received from the memory circuit 120.

As a result of the separation of the DQ pins into the set of test and data I/O pins 140 and the set of data I/O pins 150, an external testing device need attach itself only to the test and data I/O pins 140 to successfully receive the compressed data.

FIG. 2 is a diagram of an output compression element from the memory test circuit of FIG. 1 according to disclosed embodiments. As shown in FIG. 2, the output compression element 130 includes a data pattern generator 210, a compare circuit 220, an output data selector 230, and a control circuit 240.

The data pattern generator 210 receives the address data from A address data lines, and uses that address data to determine a corresponding N bits of write data to be sent to a addressed memory element in the memory circuit 120 on the N total DQ pins 140 and 150. The same N bits of write data are then sent to the compare circuit as expect data.

The compare circuit 220 receives read data from the memory circuit 120 as well as a corresponding number of expect data bits from the data pattern generator 210, and compares portions of each to generate a set of compare data bits that are output as compressed data. The compare data bits represent how well the read data bits match the corresponding expect data bits. In one embodiment, the compare data bits can simply represent whether or not a subset of the read data bits exactly matches a corresponding subset of the expect data bits. The compare circuit 220 is controlled based on control signals from the control circuit 240.

In some embodiments all of the read data and expect data is provided to the compare circuit 220 at one time. In other embodiments a subset of the total read data and total expect data is provided to the compare circuit 220 at one time. The number of read data bits, expect data bits, and compare data bits can vary. However, the number of compare data bits should be lower than the number of read data bits.

Each compare data bit indicates whether two or more read data bits match a corresponding two or more bits of expect data. In some embodiments each compare data bit can represent the same number of compared read and expect data bits. In other embodiments some compare bits can represent different numbers of compared read and expect data bits than other compare bits.

The output data selector 230 receives the read data from the memory circuit and selects a fractional number of bits from the read data equal to the size of the compressed data to be output as compressed data. The output data selector 230 is controlled based on control signals from the control circuit 240. In some embodiments the possible configurations of read data elements that can be output as compressed data are fixed; in others they can be variable.

The control circuit 240 provides control signals to control the operation of the compare circuit 220 and the output data selector 230. These control signals can tell each circuit 220 and 230 when to output their data, and in some cases how to out put their data. For example, the control signals can instruct the output data selector 230 as to which portion of the read data should be output as compressed data.

In the disclosed embodiment of FIG. 2, the compare circuit 220 and the output data selector 230 are both connected directly to the compressed data output line. Some methods of isolating the outputs of these two circuits can be provided in various embodiments. For example, in one embodiment the two could use impedance control to isolate them from the compressed data output line when not using it. In other embodiments an output switch could be provided to select the output of the compare circuit 220 or the output data selector 230, as needed.

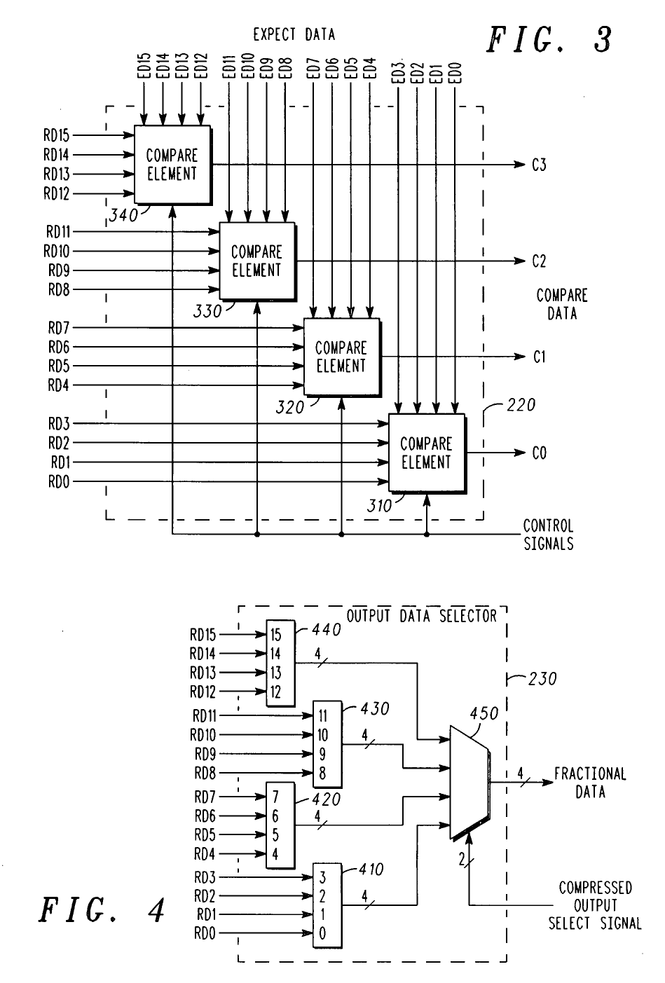

FIG. 3 is a diagram of a compare circuit from the output compression element of FIG. 2 according to disclosed embodiments. As shown in FIG. 3, the compare circuit 220 includes four individual compare elements 310, 320, 330, and 340.

Each of the four individual compare elements 310, 320, 330, and 340 is configured to compare two or more read data bits with corresponding expect data bits to generate a compare data bit indicating the success or failure of such comparison. Thus, the number of compare elements 310, 320, 330, and 340 is equal to the number of compare data bits.

In the embodiment of FIG. 2, each compare element 310, 320, 330, and 340 compares four bits of read data with a corresponding four bits of expect data to generate a corresponding compare data bit. In particular, the compare element 310 compares the outputs of read data lines RD0, RD1, RD2, and RD3 with the expect data elements ED0, ED1, ED2, and ED3, respectively, to generate the compare data bit C0; the compare element 320 compares the outputs of read data lines RD4, RD5, RD6, and RD7 with the expect data elements ED4, ED5, ED6, and ED7, respectively, to generate the compare data bit C2; the compare element 330 compares the outputs of read data lines RD8, RD9, RD10, and RD11 with the expect data elements ED8, ED9, ED10, and ED11, respectively, to generate the compare data bit C2; and the compare element 340 compares the outputs of read data lines RD12, RD13, RD14, and RD15 with the expect data elements ED12, ED13, ED14, and ED15, respectively, to generate the compare data bit C3. These compare data bits C0, C1, C2, and C3 are output as compare data on the compressed data lines.

Each compare data bit indicates whether or not the four bits of read data exactly matched the corresponding four bits of expect data. If the four bits were an exact match, the compare bit has a first value (e.g., “1”), indicating a successful read. Likewise, if any of the four read data bits did not match a corresponding compare data bit, the compare bit has a second value (e.g., “0”), indicating a failed read. Thus, a failed read only indicates that one or more of the read data bits was incorrect. It does not provide any information as to how many were incorrect, or which ones were incorrect.

For example, the compare bit C0 output from the compare element 310 indicates whether the bit output on the read data line RD0 matches the expect data bit ED0, whether the bit output on the read data line RD1 matches the expect data bit ED1, whether the bit output on the read data line RD2 matches the expect data bit ED2, and whether the bit output on the read data line RD3 matches the expect data bit ED3. If all successfully match, the compare bit C0 indicates success. If one or more fail to match, the compare bit C0 indicates failure. Comparable operations are performed in the compare elements 320, 330, and 340 to generate the compare bits C1, C2, and C3.

Alternate embodiments may employ more or fewer compare elements, and each compare element may compare more or fewer read data and expect data bits. In addition, in some alternate embodiments individual compare elements need not even compare the same number of bits. For example, in one alternate embodiments some compare elements could compare bits from three read data lines with a corresponding three expect data bits, and other compare elements could compare bits from five read data lines with a corresponding five expect data bits. It is also possible for individual compare elements to have overlap with respect to the read data and expect data they compare.

Thus, in alternate embodiments the total number of bits of compare data can be varied, and each bit of compare data can represent more or fewer bits of compared expect data and read data. And although in the disclosed embodiment each bit of compare data represents the same number of compared read data and expect data bits, some embodiments may have each compare data bit represent a different number of read data and expect data bits.

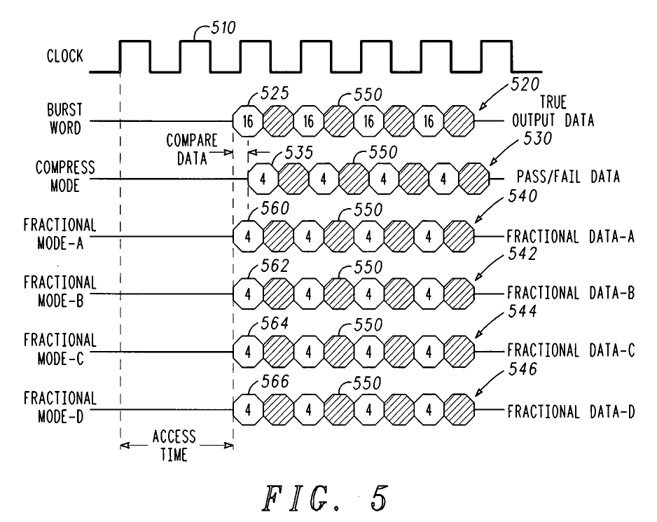

FIG. 4 is a diagram of an output data selector from the output compression element of FIG. 2 according to disclosed embodiments. As shown in FIG. 4, the output data selector 230 includes four individual storage elements 410, 420, 430, and 440, and a multiplexer 450.

The individual storage elements 410, 420, 430, and 440 each store four bits of read data received from corresponding read lines, and provides these data to the multiplexer 450. In particular, the storage element 410 stores data bits from the read data lines RD0, RD1, RD2, and RD3, the storage element 420 stores data bits from the read data lines RD4, RD5, RD6, and RD7, the storage element 430 stores data bits from the read data lines RD8, RD9, RD10, and RD11, and the storage element 440 stores data bits from the read data lines RD12, RD13, RD14, and RD15. The storage elements 410, 420, 430, and 440 may be bit registers or any other data storage element that can temporarily hold bits of data.

The multiplexer 450 receives the partial read data from each of the storage elements 410, 420, 430, and 440, and selects one set of partial read data to be output as a set of fractional data on the compressed data lines. The multiplexer 450 is controlled based on a compressed output select signal that is sent from the control circuit 240 as one of the control signals. In the embodiment of FIG. 4, the compressed output select signal is a two-bit control signal, since it needs to select one of four storage elements 410, 420, 430, and 440.

By having the multiplexer 450 cycle through all of the possible read data lines, the memory device 100 can output all of the true data from the memory circuit on the compressed data lines, allowing all of the true data to be sent via the test and data I/O pins 140. Thus, the entirety of the true data can be sent via a limited number of I/O pins. For example, in the embodiment of FIG. 4, each storage element 410, 420, 430, and 440 stores the output bits from four consecutive read data lines. By outputting the contests of each of the storage elements 410, 420, 430, and 440 in turn, the multiplexer 450 can output all sixteen bits of true data received from the sixteen read data lines RD0-RD15 along only four test and data input/output pins 140.

In alternate embodiments the number and size of the storage elements 410, 420, 430, and 440 may be varied. In fact, a single storage element could be provided that stores all of the read data bits, and the multiplexer 450 could simply select a subset of these stored bits to pass. In some embodiments in which the read data bits are kept active for a sufficiently long time, the storage elements 410, 420, 430, and 440 can be eliminated altogether, and the read data bit lines provided directly to the multiplexer 450.

In addition, although the disclosed embodiment, the multiplexer 450 passes four sequential read bits as the fractional data, this is not required. Alternate embodiments could pass any subset of the read data bits as the fractional data. Furthermore, although in the disclosed embodiment each read bit is output only once, in alternate embodiments one or more read bits could be outputted more than once.

FIG. 5 is a timing diagram of the operation of the memory test circuit of FIG. 1 according to disclosed embodiments. As shown in FIG. 5, a clock 510 coordinates the reading and writing operations during a testing mode.

A burst word 520 is generated at the data I/O pins 140 and 150 after the passage of a data access time from the relevant clock signal that starts testing. This access time is typically something that a purchaser will wish to know meets a minimum criterion, and so should be tested. For example, in some memory devices the access time should be kept below 1.5-2.0 nanoseconds. However, other memory devices could follow a different access time criterion.

The burst word 520 includes a number of data portions 525 and invalid portions 550 formed along sequential half clock cycles. As shown in FIG. 5, each data portion 525 can correspond to either the same set of data read out and repeated over multiple clock cycles, or different data read from different memory cells within a single memory circuit 120.

As noted above, however, a testing machine will typically only be connected to a portion of the total data I/O pins 140 and 150. For example, in the embodiment disclosed in FIGS. 1-4, the memory device 100 has N total data I/O pins 140 and 150, and only M data test and data I/O pins 140, where M is an integer lower than N. In the particular example show, the memory device 100 in the disclosed embodiment has 16 total I/O pins, only 4 of which are connected to a testing machine. Thus, even though all of the true data is output over all N data I/O pins, the testing circuit could only read M of them directly, and any testing data must be sent over that subset of M data I/O pins.

One way to accomplish this is to test individual blocks of data within the true data and rate them as passed or failed by block in a pass/fail data signal 530. As with the true output data 520, for half of each clock cycle, the pass/fail data signal 530 will have valid pass/fail data 535, and the other half of each clock cycle the pass/fail data signal 530 will have an invalid output 550. In the disclosed embodiment, the memory device 100 compares four blocks of four data I/O pins in a compare mode, and outputs four bits of pass/fail data 535 each clock cycle over the four test and data I/O pins 140. Alternate embodiments can vary the number of test and data I/O pins 140, as well as the size and number of blocks in the compare mode.

As noted above, the pass/fail data signal 530 will provide an indication of the success or failure of the test read/write operation in each memory cell in the memory circuit 120 and for each data I/O pin, but only with respect to blocks of the data I/O pins. No true data will be provided here.

Furthermore, because of the need to perform signal comparisons prior to generating the pass/fail data 535, the pass/fail data signal 530 will be delayed from the true data signal 520 by a compare delay. The compare delay reflects the signal delay imposed by the operation of the compare circuit 220.

Thus, if a testing machine were to attempt to measure the access time based on the pass/fail data signal 530, sent during the compare mode, it would incorrectly measure it as the actual access time plus the compare delay. This might cause the testing machine to incorrectly determine that the memory device 100 did not meet a required access time threshold when it actually did.

Therefore, the memory device 100 is designed to output the true data to the test and data I/O pins 140, in addition to the compare data. In particular, the memory unit can operate in a number of different fractional modes, each fractional mode outputting a different fractional data signal 540, 542, 544, or 546, corresponding to a different subset of the output lines of a given memory cell within the memory circuit 120. As with the true output data 520, for half of each clock cycle, each fractional data signal 540, 542, 544, or 546 will have valid fractional data 560, 562, 564, or 566, and the other half of each clock cycle fractional data signal 540, 542, 544, or 546 will have an invalid output 550.

By selecting different fractional portions of the real data at different points in time, the memory device 100 can ultimately send all of the true data over only the subset of test and data I/O pins 140. For example, in the embodiments of FIGS. 1-4, each set of fractional data 560, 562, 564, or 566 contains four bits of the corresponding sixteen-bit true output data 525. By sending the four sets of fractional data 560, 562, 564, and 566 in the four different fractional modes, the memory device 100 can send all of the true output data through the four test and data I/O pins 140.

Furthermore, since the selecting of the fractional data 560, 562, 564, or 566 imposes no significant signal delay, any access time measured based on any of the fractional data signals 540, 542, 544, or 546 will accurately reflect the actual access time.

And since this means that an external testing machine can now make an accurate measurement of the access time based on one or more of the fractional data signals 540, 542, 544, and 546, there is no need to perform an additional read/write operation in a normal mode to measure the access time. This can represent a significant time savings for the test process, since eliminating a normal mode read/write operation further eliminates an extra write operation, which can take on the order of a minute per memory device 100 in some cases.

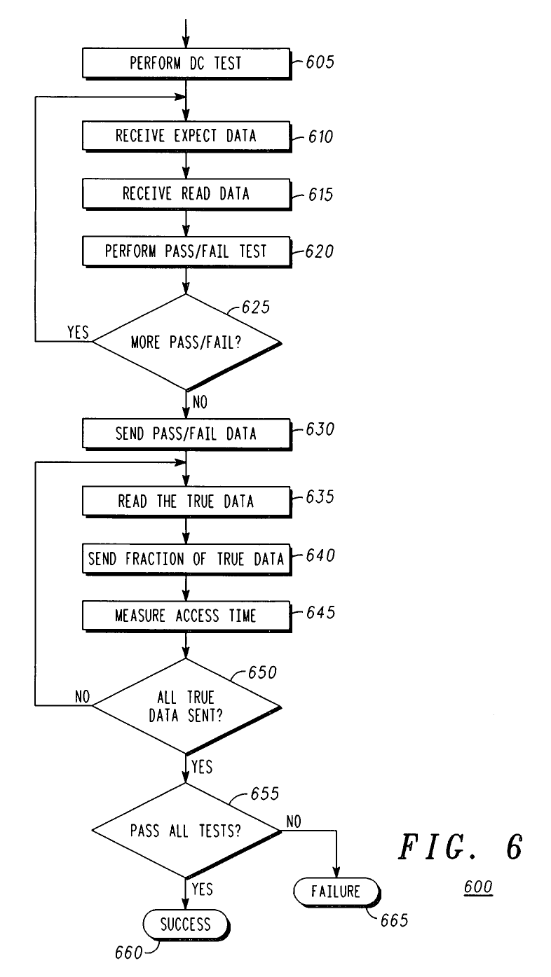

FIG. 6 is a flow chart showing a memory testing operation according to disclosed embodiments. As shown in FIG. 6, the operation begins when a output compression element 130 performs a data communication (DC) test (605).

The output compression element 130 receives a set of expect data (610) and also receives a set of read data (615). The expect data could be received either from an external source or from a source within the output compression element 130, and represents a subset of the total expect data. The read data is read from the data I/O lines of the memory circuit 120 and represents a corresponding subset of the total read data.

Based on the read data and the expect data, the output compression element 130 performs a pass/fail test comparing the expect data with the read data to determine if they match (620).

Then the output compression element 130 will determine if there is more pass/fail processing to perform (625). If so, it will repeat the receiving of expect data (610), the receiving of read data (615), and the performing of a pass/fail test (620) as often as necessary. In one disclosed embodiment, the pass/fail test (620) is performed four times to generate four pass/fail results.

Although elements 610, 615, 620, and 625 show an iterative process to perform all needed pass/fail tests, this processing could be done in parallel, allowing all of the pass/fail tests to be performed at the same time by different compare elements. In such an embodiment, the output compression element 130 need only receive each of the expect data and the read data once, and simply perform the pass/fail tests on subsets of those received signals.

Once the output compression element 130 determines that pass/fail processing is completed (625), it will then send the total pass/fail data over the test and data I/O pins that are being used during a testing process (630). This total pass/fail data can be sent to an external testing machine that is performing memory tests on the memory device 100 as a whole.

The output compression element 130 will then proceed to read the true data from the memory circuit 120 (635), and sends a fraction of the true data over the test and data I/O pins that are being used during a testing process (640). In some embodiments all of the true data is read, and a fraction of the true data is selected to be output. In other embodiments, only a fraction of the true data is actually read from the memory circuit 120 for this operation.

Once it receives the fractional data, an external testing machine can both determine the accuracy of the fractional data, as well as measure the access time required to read that fractional portion of the true data (645).

The output compression element 130 will then determine if all the true data has been sent (i.e., if there is more fractional data yet to send) (650). If so, it will repeat the reading of the true data (635), the sending of the fraction of the true data (640), and the measuring of the access time (645), and the as often as necessary. In one disclosed embodiment, the sending of the fractional data (640) is performed four times, each time passing ¼^{th} of the true data.

In some embodiments the operation of measuring the access time (645) need only be performed only once, and can be omitted in later iterations. In other embodiments the access time can be measured (645) during each iteration of the sending of a fraction of the true data (645).

After the output compression element 130 determines that all the true data has been sent (650), the testing machine can then determine whether the memory device 100 passes all of the relevant memory tests (655). If it determines that the memory device 100 has passed all the tests, then it certifies the memory device 100 as successfully tested (660). If, however, it determines that the memory unit has not passed all the tests, then the testing machine certifies the memory device 100 as having failed testing (665).

Although FIG. 6 describes a method in which the pass/fail testing operation is performed before a fractional data output operation, this is by way of example. In alternate embodiments the timing of the operations could be switched, or even interleaved with each other.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiments were chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled. The various circuits described above can be implemented in discrete circuits or integrated circuits, as desired by implementation.

What is claimed is:

1. A memory test circuit, comprising:
an output data selector configured to receive the plurality of read data bits and output a fraction of the plurality of read data bits as a plurality of fractional data bits; and
a control circuit configured to select a set of bit positions in the plurality of read data bits whose corresponding values will form the plurality of fractional data bits,
wherein the selected set of bit positions is selectable from a plurality of possible sets of bit positions, each actual bit position in the plurality of read data bits being contained in at least one of the possible sets of bit positions, and
wherein a fractional length of the plurality of fractional data bits is smaller than a full length of the plurality of read data bits.

2. The memory test circuit of claim 1, further comprising:
a data pattern generator configured to provide a plurality of expect data bits; and
a compare circuit configured to compare a plurality of received read data bits and the plurality of received expect data bits to generate one or more compare data bits,
wherein a compare length of the one or more compare bits is smaller than the full length.

3. The memory test circuit of claim 2, wherein the compare circuit comprises:
a plurality of compare elements, each for comparing one or more bits from the plurality of read bits with a corresponding one or more bits from the plurality of expect data bits.

4. The memory test circuit of claim 3, wherein the plurality of compare elements consists essentially of a number of compare elements equal to the fractional length.

5. The memory test circuit of claim 2, further comprising a control circuit configured to control operation of the compare circuit and the output data selector.

6. The memory test circuit of claim 1, wherein the output data selector comprises:
a plurality of registers, each configured to store a selected plurality of bits chosen to correspond to one of the possible sets of bit positions in the plurality of read data bits, the selected plurality of bits for each of the plurality of registers having a selected length equal to the fractional length; and
a selection element configured to select and output of the selected plurality of bits from one of the plurality of registers as the fractional data, in response to a control signal.

7. A memory chip, comprising:
a memory element having a plurality of bit storage elements;
a data pattern generator configured to provide a plurality of write data bits and a plurality of expect data bits corresponding to the plurality of write data bits;
a compare circuit configured to receive a plurality of read data bits from the memory element, and to compare the plurality of read data bits and the plurality of expect data bits to generate one or more compare data bits;
an output data selector configured to receive the plurality of read data bits and output a fraction of the plurality of read data bits as a plurality of fractional data bits; and
a plurality of data input/output pins configured to receive the one or more compare data bits and the plurality of fractional data bits;
wherein a fractional length of the plurality of fractional data bits is smaller than a full length of the plurality of read data bits,
wherein a compare length of the one or more compare bits is smaller than the full length.

8. The memory chip of claim 7, wherein the compare circuit comprises:
a plurality of compare elements, each for comparing one or more bits from the plurality of read bits with a corresponding one or more bits from the plurality of expect data bits.

9. The memory chip of claim 7, wherein the output data selector comprises:
a plurality of registers, each configured to store a selected plurality of bits chosen from the plurality of read data bits, the selected plurality of bits for each of the plurality of registers having a selected length equal to the fractional length; and
a selection element configured to select and output of the selected plurality of bits from one of the plurality of registers as the fractional data, in response to a control signal.

10. The memory chip of claim 7, wherein the fractional length is an integer fraction of the full length.

11. A method of testing a memory circuit, comprising:
receiving a first set of true data from a memory unit, the first set of true data comprising a plurality of true data bits;
selecting a first fraction of the plurality of true data bits as a first plurality of fractional data bits;
outputting the first plurality of fractional data bits over a plurality of data input/output pins;
receiving a second set of true data from the memory unit after receiving the first set of true data, the second set of true data comprising the plurality of true data bits;
selecting a second fraction of the plurality of true data bits as a second plurality of fractional data bits, the second plurality of fractional data bits being selected from a different portion of the plurality of true data bits than the first plurality of fractional data bits; and
outputting the second plurality of fractional data bits over the plurality of data input/output pins;
wherein the first plurality of fractional data bits has a fractional length that is smaller than a full length of the plurality of true data bits, and
wherein the second plurality of data bits has a second fractional length that is smaller than a full length of the plurality of true data bits.

12. The method of claim 11, further comprising: measuring a data access time concurrently with receiving the first set of true data.

13. The method of claim 11, further comprising:
receiving an additional set of true data from the memory unit after receiving a previous set of true data, the additional set of true data comprising the plurality of true data bits;
selecting an additional fraction of the plurality of true data bits as an additional plurality of fractional data bits;
outputting the additional plurality of fractional data bits over the plurality of data input/output pins; and
repeating the receiving of an additional set of true data, the selecting of an additional fraction of the plurality of true data bits, and the outputting of the additional plurality of fractional data bits until bits from all bit positions in the plurality of true data bits have been sent over the plurality of data input/output pins.

14. The method of claim 11, further comprising
comparing a plurality of received read data bits and a plurality of received expect data bits to generate one or more compare data bits; and
outputting the compare data bits over the plurality of data input/output pins,
wherein a compare length of the one or more compare bits is smaller than the full length.

15. The method of claim 14, wherein the first fractional length, the second fractional length, and the compare length are all equal.

16. The method of claim 11, wherein the method is implemented in an integrated circuit.

17. A method of testing a memory circuit, comprising:
receiving a set of true data from a memory unit, the set of true data comprising a plurality of true data bits;
selecting a first fraction of the plurality of true data bits as a first plurality of fractional data bits;
outputting the first plurality of fractional data bits over a plurality of data input/output pins;
selecting a second fraction of the plurality of true data bits as a second plurality of fractional data bits, the second plurality of fractional data bits being selected from a different portion of the plurality of true data bits than the first plurality of fractional data bits; and
outputting the second plurality of fractional data bits over the plurality of data input/output pins;
wherein the first plurality of fractional data bits and the second plurality of fractional data bits both have a fractional length that is smaller than a full length of the plurality of true data bits.

18. The method of claim 17, further comprising:
selecting an additional fraction of the plurality of true data bits as an additional plurality of fractional data bits;
outputting the additional plurality of fractional data bits over the plurality of data input/output pins; and
repeating the selecting of an additional fraction of the plurality of true data bits and the outputting of the additional plurality of fractional data bits until bits from all bit positions in the plurality of true data bits have been sent over the plurality of data input/output pins.

19. The method of claim 17, further comprising
comparing a plurality of received read data bits and a plurality of received expect data bits to generate one or more compare data bits; and
outputting the compare data bits over the plurality of data input/output pins,
wherein a compare length of the one or more compare bits is smaller than the full length.

20. The method of claim 19, wherein the first fractional length, the second fractional length, and the compare length are all equal.

21. The method of claim 17, wherein the method is implemented in an integrated circuit.

22. A memory test circuit, comprising:
means for receiving a set of true data from a memory unit, the set of true data comprising a plurality of true data bits;
means for selecting a first fraction of the plurality of true data bits as a first plurality of fractional data bits;
means for outputting the first plurality of fractional data bits over a plurality of data input/output pins;
means for selecting a second fraction of the plurality of true data bits as a second plurality of fractional data bits, the second plurality of data bits being selected from a different portion of the plurality of true data bits than the first plurality of fractional data bits; and
means for outputting the second plurality of fractional data bits over the plurality of data input/output pins;
wherein a first fractional length of the first plurality of fractional data bits is smaller than a full length of the plurality of read data bits,
wherein a second fractional length of the second plurality of fractional data bits is smaller than the full length of the plurality of read data bits.

23. The memory test circuit of claim 22, further comprising:
means for selecting an additional fraction of the plurality of true data bits as an additional plurality of fractional data bits; and
means for outputting the additional plurality of fractional data bits over the plurality of data input/output pins.

24. The memory test circuit of claim 22, further comprising
means for comparing a plurality of received read data bits and a plurality of received expect data bits to generate one or more compare data bits; and
means for outputting the compare data bits over the plurality of data input/output pins,
wherein a compare length of the one or more compare bits is smaller than the full length.

25. The memory test circuit of claim 22, wherein the method is implemented in an integrated circuit.
